(19) United States
(12) Patent Application Publication
(10) Pub. No.: US 2005/0230758 A1
(43) Pub. Date: Oct. 20, 2005

(54) Transistor well bias scheme

(76) Inventor: Remi LeReverend, San Diego, CA (US)

Correspondence Address: KNOBBE MARTENS OLSON & BEAR LLP, 2040 MAIN STREET, FOURTEENTH FLOOR, IRVINE, CA, 92614, US

(21) Appl. No.: 10/826,891

(22) Filed: Apr. 16, 2004

(51) Int. Cl. H01L 29/76

(52) U.S. Cl. 257/368

(57) ABSTRACT

A method of reducing the operating voltage level of a MOS transistor formed in a well, comprising drawing a current from the well and thereby forward biasing the well, while the well potential is allowed to vary according to inherent transistor characteristics.

### BACKGROUND OF THE INVENTION

1. Field of the Invention

The present invention relates generally to a structure and method for biasing a transistor well, and more particularly to a structure and method for reducing the minimum supply voltage for a transistor circuit.

2. Description of the Related Art

Circuits including transistors, such as Metal-Oxide-Silicon (MOS) Field Effect Transistors (FET), have a minimum supply voltage for operation. This minimum supply voltage is characterized as the sum of at least one gate to source voltage (V_{gs}) and one saturation voltage (V_{dsat}). A number of techniques have been developed to reduce this supply voltage limit for low voltage and low power implementation environments of MOS transistors. Such techniques include, for example, forcing a predefined voltage on the well of the transistor to reduce the gate to source voltage, use of a special technology variant providing MOS transistors with low threshold voltage, and floating-gate MOS technology wherein the threshold voltage of each MOS device can be programmed.

Although these techniques are useful in many applications, additional methods to reduce the supply voltage required to operate a transistor-based circuit would be beneficial for low voltage transistor circuits, as well as for any circuit design for reduced operating voltage and power consumption.

### SUMMARY OF THE INVENTION

In one aspect of the invention, in a circuit comprising at least one MOS transistor and external circuitry to forward bias a well of said MOS transistor, a method of biasing the well comprises determining a bias current to be drawn from said well, and biasing the well by drawing the determined bias current from the well with the external circuitry. The external circuitry may comprise a transistor, and the circuit may comprise a differential amplifier.

In another aspect of the invention, a differential amplifier circuit comprises a first MOS transistor formed in a well and comprising a gate terminal configured as a first input to the differential amplifier, and a source terminal, and a second MOS transistor formed in a well and comprising a gate terminal configured as a second input to the differential amplifier, and a source terminal coupled to the source terminal of the first MOS transistor, wherein the well of the first MOS transistor is coupled to the well of the second MOS transistor. The differential amplifier further comprises a third MOS transistor comprising a source terminal coupled to a voltage source and a drain coupled to the source terminals of the first and second MOS transistors, and a transistor current source coupled to at least the well of the first MOS transistor so as to draw a current from the well. In a further aspect of the invention, the transistor current source may be coupled to the well of the second MOS transistor so as to draw a current from the well.

In an additional aspect of the invention, a circuit comprises two or more transistors formed in wells coupled to different biasing circuits, wherein a current drawn from the wells is substantially the same, and wherein the well potentials are different. At least one of the biasing circuits may comprise a transistor coupled to at least one of the wells and configured to draw a current from the well.

In yet another aspect of the invention, a method of reducing the operating voltage level of an integrated circuit comprising at least one group of two or more transistors, wherein the transistors are formed in wells, comprises forward biasing the transistor wells with a common current but not a common potential.

An additional aspect of the invention is a plurality of integrated circuits fabricated from a series of different wafers subject to process variations during wafer production, at least a portion of the integrated circuits from the series of different wafers sharing a common layout of a plurality of MOS transistors comprising wells, wherein the wells on each wafer are connected to current sources on each wafer, and wherein the current sources are configured to forward bias the wells by drawing substantially the same current from the wells, irrespective of any resulting inter-wafer or intra-wafer differences in the source to well voltage produced by the current due to process variations affecting the physical structure of the MOS transistors within or between wafers.

### BRIEF DESCRIPTION OF THE DRAWINGS

FIG. 1 is a cross-section illustration of a MOS transistor.

FIG. 2 is a schematic diagram of the MOS transistor of FIG. 1.

FIG. 3 is a flow diagram illustrating one embodiment of a method of biasing a transistor well.

FIG. 4 is a schematic diagram of a MOS transistor differential amplifier circuit.

FIG. 5 is a schematic diagram of a MOS transistor differential amplifier circuit implementing a well bias scheme according to one embodiment of the invention.

FIG. 6 is a schematic diagram of a MOS transistor differential amplifier circuit implementing another embodiment of a well bias circuit.

### DETAILED DESCRIPTION OF THE PREFERRED EMBODIMENT

Embodiments of the invention will now be described with reference to the accompanying Figures, wherein like numerals refer to like elements throughout. The terminology used in the description presented herein is not intended to be interpreted in any limited or restrictive manner, simply because it is being utilized in conjunction with a detailed description of certain specific embodiments of the invention. Furthermore, embodiments of the invention may include several novel features, no single one of which is solely responsible for its desirable attributes or which is essential to practicing the inventions herein described.

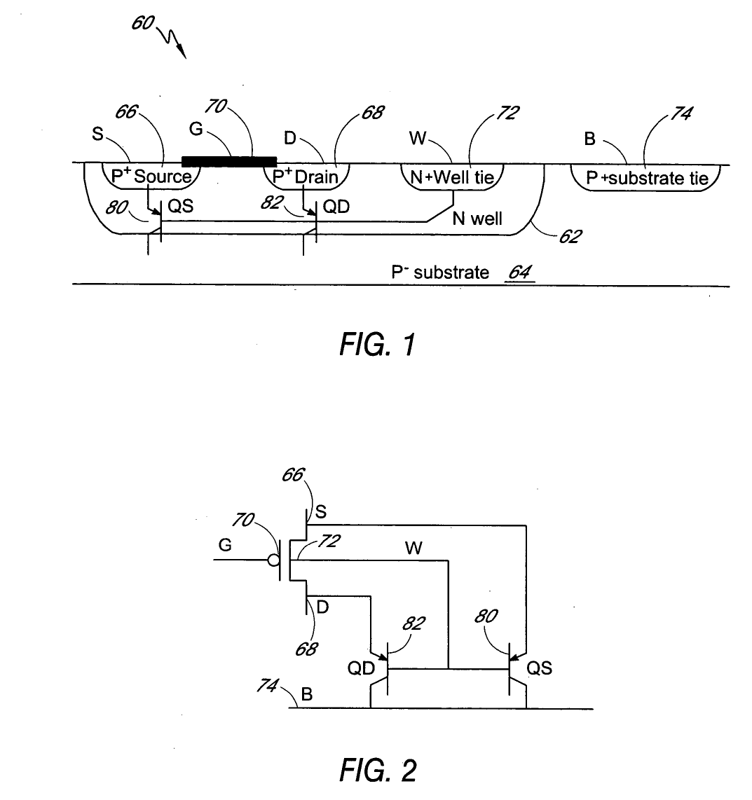

FIG. 1 is a cross-section illustration of a PMOS transistor 60. The transistor is formed in an n-well 62 on a p-type substrate 64, and comprises a source 66, drain 68, gate 70, well tie 72, and body tie 74. An equivalent five-terminal model of the PMOS transistor 60 is illustrated in FIG. 2, including parasitic PNP bipolar junction transistors (BJT's) QS 80 and QD 82 coupled to the body tie 74 of the device 60.

In order to reduce the minimum gate to source voltage level for operation of the PMOS transistor, the source-to-well diode of the transistor can be forward biased by drawing a current from the well. When forward biasing the well of a PMOS transistor in a differential amplifier circuit, the current through the well-source junction advantageously remains negligible as compared to the other currents in the differential pair. This is difficult to achieve when the well is biased with a voltage, because the well is forced to a predefined potential with a voltage source, and the voltage-current characteristic of the well-source junction is affected by process variations in the transistor. Thus, the bias current is poorly controlled. However, biasing the well with a predefined current as described herein avoids such a drawback, wherein the current is controlled, and the voltage drop is determined by the well-source junction itself rather than a forced, predefined voltage.

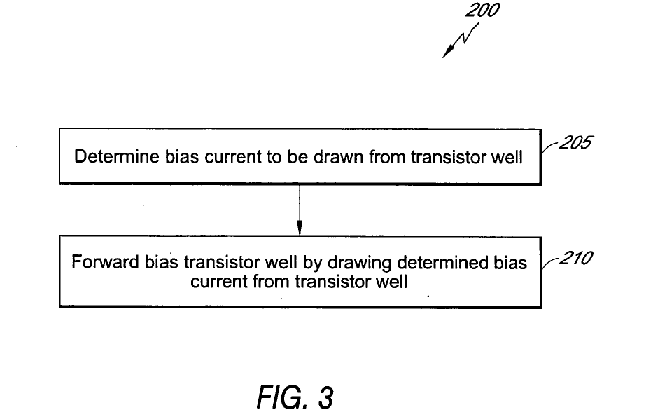

One embodiment of a method 200 of biasing a transistor well in a circuit comprising a MOS transistor formed in a well is illustrated in the flow diagram of FIG. 3. The method comprises determining a bias current to be drawn from the transistor well in order to bias the well in a step 205. In a step 210, the transistor well is forward biased by drawing the bias current determined in step 205 from the well with external circuitry.

In one embodiment, the biasing method 200 is implemented in a circuit comprising a plurality of transistors formed in wells, such that the transistors are biased in step 205 by drawing a common current from the wells of the plurality of transistors while the well potentials are allowed to vary. For example, the wells of a plurality of transistors can be tied to different biasing circuits such that substantially the same current is drawn from the wells of the transistors and the wells are forward biased, but the well potential at each individual transistor can vary according to physical transistor characteristics. This configuration is especially applicable to integrated circuits fabricated from a series of different wafers, wherein the physical characteristics of the well to source junctions of each transistor in the integrated circuits differ due to process or material variations within or between wafers.

This method of biasing the transistor well will be further described herein in reference to the implementation of one embodiment of the method in an amplifier circuit, wherein the input range of the amplifier can be increased by implementing the biasing scheme described herein. It will be appreciated by those skilled in the art that the methods described herein are not limited to amplifier circuits and are only exemplary in nature.

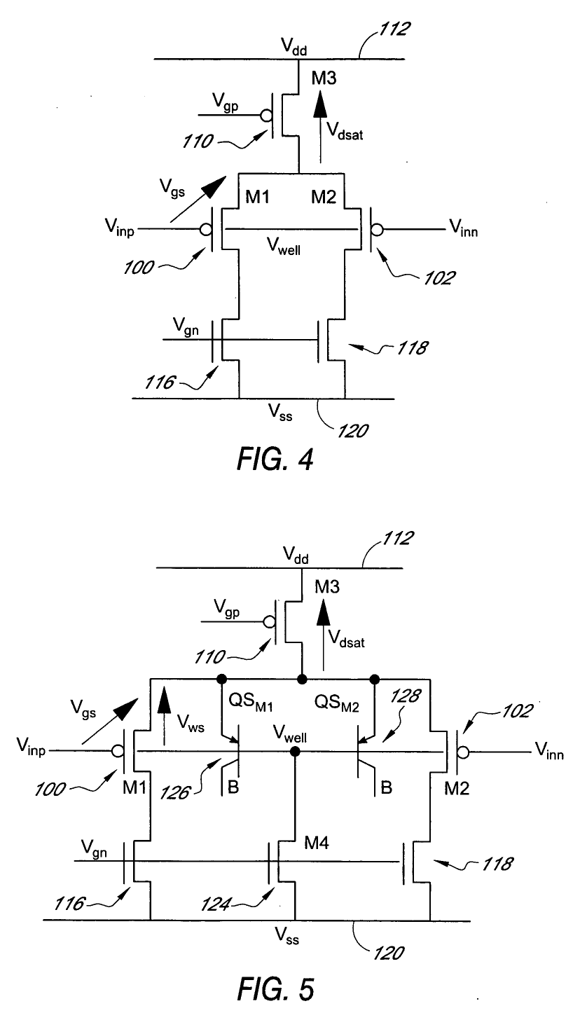

FIG. 4 is a schematic diagram of a CMOS differential or source coupled pair amplifier circuit 90, where first and second PMOS transistors are coupled in a common source configuration. The amplifier circuit 90 comprises a first PMOS transistor M1 100 and a second PMOS transistor M2 102 having a common source and common well connection. The common source of transistors M1 100 and M2 102 is coupled to the drain of a third PMOS transistor M3 110, and the source of transistor M3 110 is coupled to a first voltage source V_{dd} 112. The drain terminals of transistors M1 100 and M2 102 are coupled to NMOS transistors 116, 118, wherein the NMOS transistors 116, 118 are coupled in a common gate configuration with their source terminals connected to a second voltage source Vₛₛ 120 (or circuit common, depending on the circuit design and implementation environment).

The gate terminals of transistors M1 100 and M2 102 function as the positive input vᵢₙₚ and negative input vᵢₙₙ, respectively, of the differential amplifier 90. The input range of the amplifier for vᵢₙₚ is limited by the gate to source voltage V_{gs} of transistor M1 100 and the saturation voltage V_{dsat} of transistor M3. The input range voltage Vᵢₙₘₐₓ can be expressed by Equation (1).
V_{in max}=V_{dd}−V_{dsat}_{_{M3}}−V_{gs}_{_{M1}} (1)

Assuming the voltage at the well is the same as the voltage at the source (V_{ws} is zero), the gate to source voltage V_{gs} is given by Equation (2), wherein Vₜ is the gate threshold voltage for channel equilibrium.
V_{gs}=Vₜ+V_{overdrive} (2)

The device overdrive voltage depends on the inversion regime of transistor M1 100. Under strong inversion and saturation conditions, the overdrive voltage can be expressed, for example, by Equation (3), wherein I_{d} is the drain current.

$${V}_{overdrive} = \sqrt{\frac{2 \cdot n \cdot {I}_{d}}{β}} \qquad ( 3 )$$

For additional discussion of the above expressions and related definitions, see Eric A. Vittoz, Micropower Techniques, in DESIGN OF VLSI CIRCUITS FOR TELECOMMUNICATION AND SIGNAL PROCESSING 53-97 (J. E. Franca & Y. P. Tsividis eds., 1994), hereby incorporated by reference.

According to one embodiment of a transistor well bias scheme, an additional device can be included in the amplifier circuit 90 to draw a current from the wells of the PMOS devices 100, 102. As illustrated in FIG. 5, an NMOS transistor M4 124 is coupled between the wells of the PMOS devices 100, 102 and the second voltage source Vₛₛ 120. Inherent PNP parasitic bipolar transistors 126, 128 for the source connections of PMOS transistors M1 100 and M2 102 are also illustrated in FIG. 5. With the addition of transistor M4 124, the gate to source voltage (V_{gsM1}) of transistor M1 100 can be expressed according to Equation (4), where n is the weak inversion slope and is usually smaller than two:
V_{gs}_{_{M1}}=Vₜ+V_{overdrive}−(n−1)·V_{ws} (4)

The well to source voltage V_{ws} for each PMOS device M1 100 and M2 102 is given by the base-emitter junction of bipolar transistor QS_{M1,2}, and can be expressed according to Equation (5), where

$$\frac{kT}{q}$$

is the thermal voltage, Iₛ is the theoretical reverse saturation current of each PNP transistor, I_{b} is the base current of each parasitic PNP device 126, 128, and β_{F} is the forward current gain.

$${V}_{ws} = \frac{kT}{q} \cdot ln ( \frac{{β}_{F} \cdot {I}_{b}}{{I}_{s}} ) \qquad ( 5 )$$

In the present example, the base current I_{b} of each of the parasitic bipolar transistors 126, 128 is half of the drain-source current through transistor M4 (I_{b}=I_{dsM4}/2), assuming the differential pair is symmetrical. In one embodiment, the product of β_{F} and the drain-source current through M4 is approximately a tenth of the drain-source current through transistor M3 or less (I_{dsM4}×β_{F}≦I_{dsM3}/10). As the gate to source voltage of transistor M1 100 is decreased by the well to source voltage multiplied by a factor of (n−1), the maximum input voltage of the amplifier is also decreased for a given V_{dd}. Subsequently, for the same input voltage range, the minimum supply voltage for operation of the circuit is lowered by the same amount, i.e., the well to source voltage multiplied by (n−1). Thus, the input range for the amplifier is increased and the minimum operating voltage of the input transistor M1 100 is decreased by drawing a current from the transistor well.

In reference to the above discussion of the method 200 illustrated in FIG. 3 and the amplifier circuit of FIG. 5, transistor M4 124 and a corresponding drive voltage are selected according to a total current level to be drawn from the wells of transistors M1 100 and M2 102. Thereby, the well-to-source voltages of each transistor M1 100 and M2 102 are allowed to vary according to their physical characteristics rather than forcing the well-to-source voltage to a predefined potential in order to bias the wells.

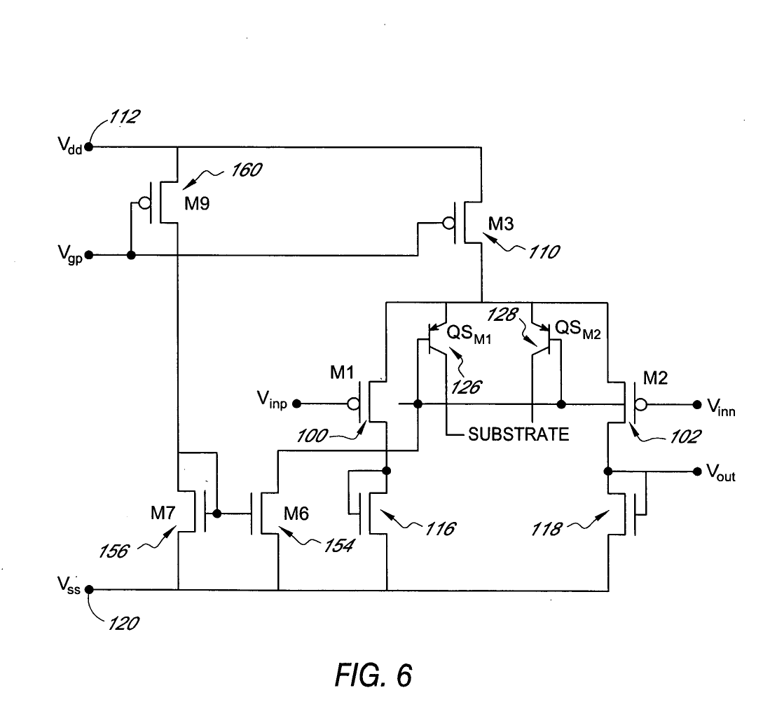

Another embodiment of a transistor well bias circuit is illustrated in FIG. 6, wherein a bias current is drawn from the wells of transistors M1 100 and M2 102 by current mirror transistor M6 154. The amount of current drawn from the wells of these transistors is controlled by adjusting the reference current through mirrored transistor M7 156. Mirrored transistor M7 156 is coupled to a control transistor M9 310, which is coupled to the first voltage source V_{dd} 112. The gate terminal of transistor M9 160 is coupled to the gate terminal of transistor M3 110.

The voltage level at the gate terminal V_{gp} of control transistor M9 310 is adjusted to control the level of current through mirrored transistor M7 306. Thereby, the amount of current through mirroring transistor M6 304, and drawn from the wells of transistors M1 100 and M2 102, is adjusted accordingly.

It will be appreciated by those skilled in the art that the transistor well bias methods described herein are applicable to both NMOS and PMOS transistor devices and are not limited to the embodiments described and illustrated. Furthermore, the invention is not limited to amplifiers and can be implemented in a variety of circuit environments, and the circuit for drawing a current from the transistor well can include a plurality of elements or devices.

The foregoing description details certain embodiments of the invention. It will be appreciated, however, that no matter how detailed the foregoing appears in text, the invention can be practiced in many ways. As is also stated above, it should be noted that the use of particular terminology when describing certain features or aspects of the invention should not be taken to imply that the terminology is being re-defined herein to be restricted to including any specific characteristics of the features or aspects of the invention with which that terminology is associated. The scope of the invention should therefore be construed in accordance with the appended claims and any equivalents thereof.

1. In a circuit comprising at least one MOS transistor and external circuitry to forward bias a well of said MOS transistor, a method of biasing said well comprising:
determining a bias current to be drawn from said well; and
biasing said well by drawing said determined bias current from said well with said external circuitry.

2. The method of claim 1, wherein said external circuitry comprises a transistor.

3. The method of claim 1, wherein said circuit comprises a differential amplifier.

4. A differential amplifier circuit, comprising:
a first MOS transistor formed in a well and comprising a gate terminal configured as a first input to the differential amplifier, and a source terminal;
a second MOS transistor formed in a well and comprising a gate terminal configured as a second input to the differential amplifier, and a source terminal coupled to said source terminal of said first MOS transistor, wherein said well of said first MOS transistor is coupled to said well of said second MOS transistor;
a third MOS transistor comprising a source terminal coupled to a voltage source and a drain coupled to said source terminals of said first and second MOS transistors; and
a transistor current source coupled to at least said well of said first MOS transistor so as to draw a current from said well.

5. The amplifier of claim 4, wherein said transistor current source is coupled to said well of said second MOS transistor so as to draw a current from said well.

6. A circuit comprising two or more transistors formed in wells coupled to different biasing circuits, wherein a current drawn from the wells is substantially the same, and wherein the well potentials are different.

7. The circuit of claim 6, wherein at least one of said biasing circuits comprises a transistor coupled to at least one of the wells and configured to draw a current from the well.

8. A method of reducing the operating voltage level of an integrated circuit comprising at least one group of two or more transistors, wherein said transistors are formed in wells, said method comprising forward biasing said transistor wells with a common current but not a common potential.

9. A plurality of integrated circuits fabricated from a series of different wafers subject to process variations during wafer production, at least a portion of said integrated circuits from said series of different wafers sharing a common layout of a plurality of MOS transistors comprising wells;
wherein said wells on each wafer are connected to current sources on each wafer, and
wherein said current sources are configured to forward bias said wells by drawing substantially the same current from said wells, irrespective of any resulting inter-wafer or intra-wafer differences in the source to well voltage produced by said current due to process variations affecting the physical structure of the MOS transistors within or between wafers.
